(19) United States
(12) Patent Application Publication
(10) Pub. No.: US 2024/0405092 A1
(43) Pub. Date: Dec. 5, 2024

(54) SEMICONDUCTOR DEVICE COMPRISING A HIGH-K GATE DIELECTRIC MULTILAYER LAMINATE STRUCTURE AND A METHOD FOR MANUFACTURING THEREOF

(71) Applicant: Infineon Technologies AG, Neubiberg (DE)

(72) Inventors: Armin TILKE, Dresden (DE); Sandra KRAUSE, Dresden (DE); Thomas AICHINGER, Faak am See (AT); Wolfgang LEHNERT, Freudenberg GT Lintach (DE); Francisco Javier SANTOS RODRIGUEZ, St. Jakob im Rosental (AT)

(21) Appl. No.: 18/664,904

(22) Filed: May 15, 2024

(30) Foreign Application Priority Data
May 31, 2023 (DE) 102023205087.0
Mar. 27, 2024 (DE) 102024202924.6

(51) Int. Cl. H01L 29/51; H01L 29/16; H01L 29/423

(52) U.S. Cl. CPC H01L 29/512; H01L 29/1608; H01L 29/4236; H01L 29/42368; H01L 29/517

(57) ABSTRACT

There is described a semiconductor device comprising an SiC body with a gate structure comprising a gate dielectric with a specific multilayer laminate structure including alternating layers of a first dielectric material and of a second dielectric material having a dielectric constant of 4 or higher. There is further described a method for manufacturing such a semiconductor device including an SiC body as mentioned before.

### RELATED APPLICATION

This application claims priority to German Patent Application No. 102023205087.0, filed on May 31, 2023, entitled “SEMICONDUCTOR DEVICE COMPRISING A HIGH-K GATE DIELECTRIC MULTILAYER LAMINATE STRUCTURE AND A METHOD FOR MANUFACTURING THEREOF”, and German Patent Application No. 102024202924.6, filed on Mar. 27, 2024, entitled “SEMICONDUCTOR DEVICE COMPRISING A HIGH-K GATE DIELECTRIC MULTILAYER LAMINATE STRUCTURE AND A METHOD FOR MANUFACTURING THEREOF”. German Patent Application No. 102023205087.0 and German Patent Application No. 102024202924.6 are incorporated by reference herein in their entirety.

### TECHNICAL FIELD

The present disclosure relates to semiconductor devices and a method of manufacturing thereof. In particular, this description relates to semiconductor devices, such as, for example, those comprising a silicon carbide (SiC) body, with high-k gate dielectric multilayer laminate structures.

### BACKGROUND

In the manufacturing of semiconductors, it is desirable to improve transistor performance even as devices become smaller due to ongoing scaling. The reduced scaling with conventional gate dielectrics generally creates problems in the reliability of, among others, MOS transistors because of, for example, short channeling effects. SiO₂ dielectric materials can be replaced with high-k dielectric materials to improve device performance as the actual thickness of the dielectric can be reduced by providing a similar equivalent oxide thickness (EOT). However, significant electron tunneling effects are described due to the lower band offsets of high-k gate materials compared to SiO₂.

In the light of the above, the present disclosure is intended to solve the above problems and to improve the performance of semiconductor devices, especially, those with an SiC body, at the same time as to reduce the scaling of those semiconductor devices.

### SUMMARY

According to an embodiment, a semiconductor device may comprise a silicon carbide body, in the following SiC body, comprising a drift region of a first conductivity type, a body region of a second conductivity type, a source region of the first conductivity type, and a gate structure. The gate structure may comprise a gate electrode and a gate dielectric that isolates the gate electrode from the SiC body, wherein the gate structure may be disposed adjacent to the source region, the body region and the drift region. The gate dielectric may comprise a multilayer laminate structure including alternating layers of a first dielectric material and of a second dielectric material, wherein the first and the second dielectric materials have a dielectric constant (k value) of 4 or higher. According to an embodiment, the first dielectric material may have an at least 0.3 eV higher conduction band offset and an at least 0.3 eV lower valence band offset than the second dielectric material or vice versa. In the context of the present disclosure, the valence band offset and the conduction band offset is calculated to the silicon carbide valence band and the silicon carbide conduction band, respectively, if not described in a different manner.

According to a further embodiment, the first dielectric material may have a high conduction band offset but low valence band offset and the second dielectric material may have a low conduction band offset but high valence band offset or vice versa. This specific arrangement of the multilayer laminate in the gate dielectric combines the possibility to use materials with high-k values in the gate dielectric stack without excessive tunneling currents across it.

In line with the terms “high” and “low”, it means that the energy levels of the conduction bands or valence bands, respectively, have an offset of at least 1.0 eV, more particularly, 1.5 eV or more, to be considered as being high enough to suppress carrier tunneling through the gate dielectric. An offset is considered to be low if the energy level of the dielectric has a difference to the valence or conduction band, respectively, of less than 1.0 eV, more particularly of 0.7 eV or less.

In another embodiment, a semiconductor device may comprise a SiC body, comprising a drift region of a first conductivity type, a body region of a second conductivity type, a source region of the first conductivity type, and a gate structure. The gate structure may comprise a gate electrode and a gate dielectric that isolates the gate electrode from the SiC body, wherein the gate structure is disposed adjacent to the source region, the body region and the drift region. The gate dielectric according to this embodiment may comprise a multilayer laminate structure including alternating layers of a first dielectric material comprising or being silicon oxide and of a second dielectric material having a dielectric constant (k value) of 4 or higher, wherein the thickness of the layers of the first dielectric material is at most 5 nm, and the gate dielectric includes layers of the first dielectric material as the first and the last layers of the multilayer laminate structure. This multilayer laminate in combination with a regular gate dielectric, such as, for example, silicon oxide, in the gate dielectric allows the use of materials with high-k values in the gate dielectric stack for reducing the thickness of the gate dielectric and avoids excessive tunneling currents across it at the same time due to the higher dielectric constant of the dielectric material used in the multilayer laminate structure.

The disclosure further describes a method for manufacturing a semiconductor device including a silicon carbide (SiC) body, wherein the SiC body may comprise a drift region of a first conductivity type, a body region of a second conductivity type, and a source region of the first conductivity type. The SiC body may be provided with a gate structure comprising a gate electrode and a gate dielectric that isolates the gate electrode from the SiC body, wherein the gate structure may be disposed adjacent to the source region, the body region and the drift region. In this embodiment, the gate dielectric may be deposited on parts of the SiC body in a multilayer laminate structure including alternating layers of a first dielectric material and of a second dielectric material, wherein the first and the second dielectric materials have a dielectric constant (k value) of 4 or higher. According to an embodiment, the first dielectric material has an at least 0.3 eV higher conduction band offset and an at least 0.3 eV lower valence band offset than the second dielectric material or vice versa. According to another embodiment, the first dielectric material has a high conduction band offset but low valence band offset and the second dielectric material has a low conduction band offset but high valence band offset or vice versa, wherein the offset is calculated to the silicon carbide valence and conduction bands, respectively. According to a further alternative, the first dielectric material comprises or is silicon oxide and the second dielectric material has a dielectric constant (k value) of 4 or higher, wherein the thickness of the layers of the first dielectric material is at most 5 nm, and the gate dielectric includes layers of the first dielectric material as the first and the last layers of the multilayer laminate structure. The method of specifically stacking high-k materials in the gate dielectric stack enables the scale reduction of the obtained semiconductor devices and an interface workfunction engineering for improving the reliability and performance of these semiconductor devices.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a semiconductor device according to a first embodiment comprising a planar MOSFET concept having a gate dielectric in a multilayer laminate structure.

FIG. 2 illustrates a semiconductor device according to a second embodiment comprising a trench MOSFET concept having a gate dielectric in a multilayer laminate structure.

FIG. 3 illustrates a semiconductor device according to a third embodiment comprising a planar MOSFET concept having a gate dielectric in a multilayer laminate structure and a source metal with interlayer dielectric.

FIG. 4 illustrates a semiconductor device according to a fourth embodiment comprising a trench MOSFET concept having a gate dielectric in a multilayer laminate structure and a source metal with interlayer dielectric.

FIG. 5 illustrates a band diagram of a gate dielectric in a multilayer laminate structure according to an embodiment of the application.

FIG. 6 illustrates a band diagram of a gate dielectric in a multilayer laminate structure according to a further embodiment of the application.

FIG. 7 illustrates a band diagram of a gate dielectric in a multilayer laminate structure according to still a further embodiment of the application.

FIG. 8 illustrates a band diagram of a gate dielectric in a multilayer laminate structure according to a further alternative embodiment of the application.

FIG. 9 illustrates a band diagram of a gate dielectric in a multilayer laminate structure according to a further alternative embodiment of the application.

### DETAILED DESCRIPTION

In a general aspect the semiconductor devices described herein are based on wide bandgap materials, especially power semiconductor devices comprising SiC substrates, for example. Examples of such semiconductor devices with specific dielectric gate structures include metal oxide semiconductor field-effect transistors (MOSFETs), junction field-effect transistors (JFETs), or insulated gate bipolar transistors (IGBTs). Any other semiconductor devices with a dielectric gate structure are included in the general concept of the present disclosure even if they are not literally mentioned herein. Wide bandgap semiconductor devices generally are able to sustain breakdown voltages higher than conventional silicon power devices. Those semiconductor devices may comprise a SiC body having a drift region of a first conductivity type, a body region of a second conductivity type, a source region of the first conductivity type and a gate structure comprising a gate electrode and a gate dielectric that isolates the gate electrode from the SiC body, wherein the gate structure is disposed adjacent to the source region, the body region and the drift region. Even though all examples are described with regard to semiconductor devices having a SiC body, the present concept may be implemented into other wide bandgap semiconductor devices based on, for example, GaN, AlN, Ga₂O₃, and so forth.

A drift region of a first conductivity type may be prepared by doping the respective region of the SiC body. In the same way, the source region may be prepared by doping the respective region of the SiC body. Depending on the type of the semiconductor device, first conductivity type may mean a doping with negative charge carriers and a second conductivity type may mean a doping with positive charge carriers (holes), for example, or vice versa. For each embodiment the general conductivity of the first or second type shall be the same, however, different charge carrier concentrations may be used within one conductivity type respectively, also known as n⁺ or n⁻ or p⁺ or p⁻ doped substrates or active regions.

The SiC body may include a well region with higher doping levels for increasing the charge transfer through the conductivity channel. Furthermore, the SiC body may include SiC epitaxial layers of the same conductivity type as the drift region of the SiC body. Moreover, a drain electrode may be provided adjacent to the drift region of the SiC body and/or the SiC epitaxial layers. Generally, the herein described dielectric structures may be used in n-channel or p-channel transistors.

Generally, planar type semiconductor devices can include a gate structure which may extend between the source region and the drain region. The gate structure may be disposed on a portion of the source region and a portion of the drain region. In some examples, a first source region and a second source region may be provided within one pnp junction as described herein. Then, the gate structure may be disposed on the SiC body and may be disposed on a portion of the first source region and on a portion of the second source region.

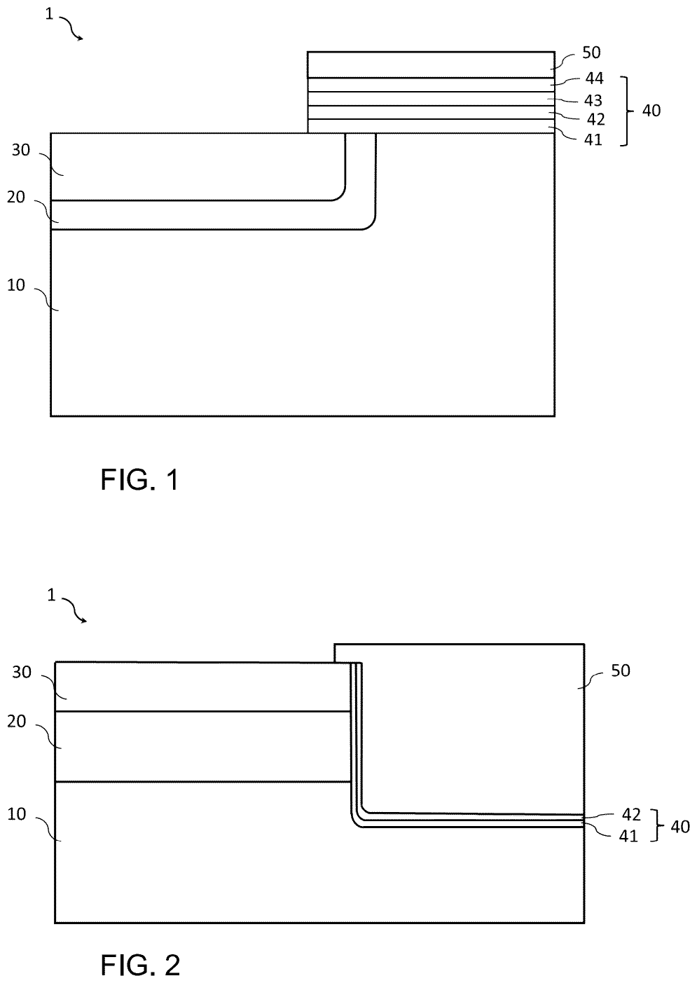

In FIG. 1, a planar type MOSFET is shown as an example of a semiconductor device 1 described herein. More particularly, a half cell of such a transistor is shown, while further cell structures may be individually configured in the same or a different conventional technique. The semiconductor device 1 comprises a drift region 10 of a first conductivity type (e.g., n-doped SiC), a body region 20 of a second conductivity type (e.g., p-doped SiC), a source region 30 of the first conductivity type (e.g., n-doped SiC), and a gate structure with a gate dielectric 40 and a gate electrode 50. The gate dielectric 40 isolates the gate electrode 50 from the SiC body 20. The gate structure is deposited on a portion of the source region 30 and on a portion of the drift region 10, thereby providing a conductivity channel within the SiC body near the interface to the gate structure on which the gate structure is deposited.

A common gate dielectric used in the gate structure is a gate oxide, for example silicon oxide, especially, SiO₂. The gate dielectric usually is exposed to high electric fields in power semiconductor devices. If SiO₂ is used, the electric fields are high due to the low dielectric constant (k value of about 3.9) and the drain-source on resistance (RDSON) is limited at the same time as the operating voltage is. The semiconductor devices described herein may be provided with a specific gate dielectric structure, thereby improving the RDSON drastically compared to SiO₂ gate oxides. Moreover, due to the high electric fields in the SiO₂ in the blocking state of the transistor the gate oxide must be protected against these fields in order not to lead to a dielectric breakdown and destruction of the gate oxide. The gate structure may generally comprise a gate dielectric and a gate electrode. Exemplified gate electrodes may be from the poly-Si type or a metal gate electrode or from combination materials including a metal. Desired metal gate properties are achieved by specifically combining the gate dielectric with the respective metal gate electrode material.

In case of a SiC body the usage of a high-k dielectric becomes important because the breakdown field in SiC and SiO₂ is similar, SiO₂ as gate oxide can be damaged when a high blocking voltage is applied to the semiconductor device, such as a transistor, for example. With a high-k gate dielectric, this problem with SiO₂ gate oxide structures can be avoided. Therefore, the high-k dielectric structures as described herein can especially improve the performance of power transistors, for example. Of course, the dielectric gate structures as described herein may be used in other semiconductor technologies and may result in the same or different advantages over common oxide gate structures.

In some examples described herein, the gate dielectric 40 comprises a multilayer laminate structure including alternating layers of a first dielectric material 41,43 and of a second dielectric material 42,44, wherein the first and the second dielectric materials have a dielectric constant (also called k value or permittivity) of 4 or higher (cf. FIG. 1). Materials with a dielectric constant of more than 4 usually are known as high-k dielectrics, wherein particularly selected high-k dielectrics may have a k value of 9 or more, in particular, 20 or more. Such high-k dielectrics may be used instead of SiO₂ in the gate dielectric or in addition to SiO₂-based dielectric layers to reduce the electric field in the gate dielectric of such semiconductor devices and are suitable to achieve improvements in the breakdown performance and RDSON performance. At the same time, the gate structure may be manufactured in a smaller size while enabling similar or even better insulating properties compared to SiO₂ gate structures in the semiconductor devices with a dielectric multilayer structure as described herein.

In the examples described herein, the high-k dielectric shall act as an insulator. Therefore, the high-k dielectric structure needs a band offset sufficiently high enough to minimize or to avoid carrier and/or hole injunction into the SiC bands of the SiC body. According to the examples, the high-k dielectric structure comprises a multilayer laminate structure adapted to these demands, namely by selecting the first dielectric material such that it has a high conduction band offset but low valence band offset, and selecting the second dielectric material such that it has a low conduction band offset but high valence band offset. In this regard, the offset is calculated to the silicon carbide valence and conduction bands, respectively. More particularly, a low conduction or valence band offset does mean that it is 1.0 eV or less. This allows the use of materials with a limited band gap, for example, materials having a band gap of lower than 7.0 eV. Accordingly, either the first dielectric material or the second dielectric material provides a band offset either at the valence band or the conductive band site of the SiC body which is high enough to minimize or to avoid carrier and/or hole injunction, respectively. Instead of blocking the hole and carrier transfer by one material having a band offset to the valence and the conduction band at the same time, the blocking is carried out by two different gate dielectric materials. Because of an alternating multilayer arrangement of these two different gate dielectric materials, a sufficient suppressing or blocking of the hole and carrier transfer can be achieved.

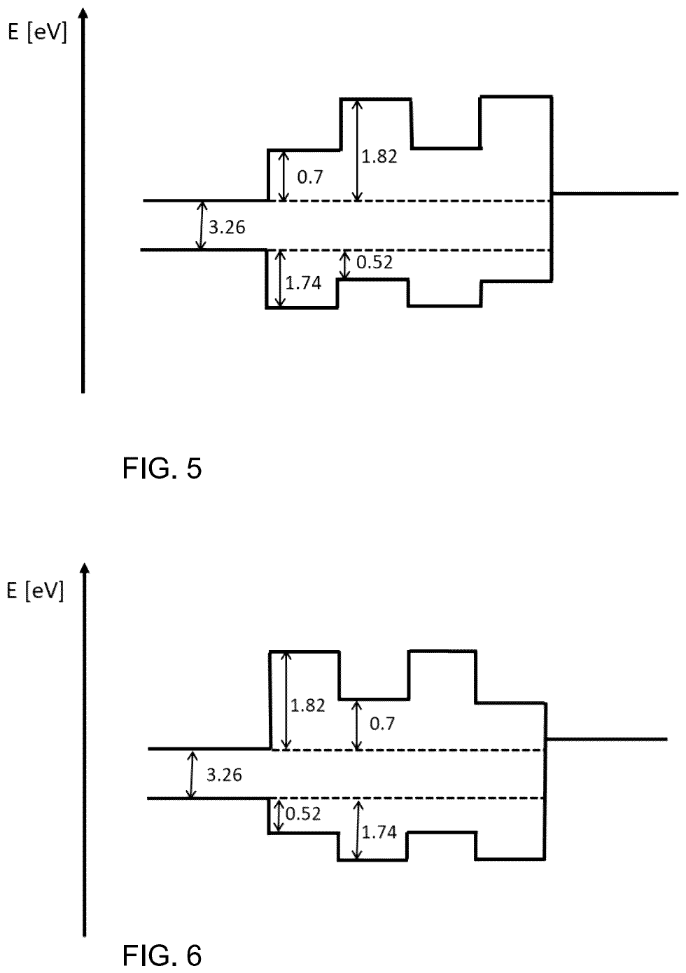

A band diagram of an example of such a multilayer dielectric structure is shown in FIG. 5. At the left-hand side, the valence and conduction band energies of the SiC body are shown. The bandgap is 3.26 eV. At the interface to SiC the energy levels of the first dielectric material layer of the multilayer laminate, here a HfO₂ dielectric layer, are shown. The conduction band offset calculated to the conduction band of the SiC body is shown as being 0.7 eV. This is considered as a low band offset in the meaning of the disclosure herein. The valence band offset is given as 1.74 eV, which is considered to be a high band offset. As next layer, a ZrO₂ dielectric layer is shown in this example. The conduction band offset is calculated to be 1.82 eV, that means a high band offset, and the valence band offset is calculated to be 0.52 eV, that means a low band offset. In this example, the energy levels of two further alternating layers of HfO₂ and ZrO₂ are shown with the respective conduction and valence band energy levels, followed by the conduction band minimum of a metal gate. This drawing shows an example of the gate dielectric multilayer structure only and different numbers of layers can be implemented in line with the herein described technical concept. Two or five or six or even more alternating dielectric layers, in particular comprising a high-k dielectric material, may be included in the multilayer laminate as described herein. The gate dielectric multilayer structure can either start and end with the first and the second gate dielectric material, or the first and the last layer of the laminate can consist of the same dielectric material, meaning either the first or the second dielectric material.

In FIG. 6, a band diagram of a further example of a semiconductor device is given. Herein the energy levels of an example with a similar general constitution of the semiconductor device as in FIG. 5 is shown, except that ZrO₂ is used as the first dielectric material and HfO₂ is used as the second dielectric material. A similar effect with regard to the charge tunneling can be achieved because alternating layers of a first high-k dielectric material with a high conduction band offset and a second high-k dielectric with a high valence band offset are combined as a multilayer laminate stack in this example.

In some examples, the gate dielectric which is provided by a multilayer structure of first and second high-k materials, in particularly, when arranged in an alternating manner, is able to provide a similar equivalent oxide thickness (EOT) compared to larger scaled devices with conventional SiO₂ gate oxide structures. As the overall gate dielectric can be prepared in a thinner layer thickness when using the multilayer structure comprising high-k dielectric materials as described herein, it is possible to meet the reduced scaling requirement of semiconductor devices, while maintaining or even improving the performance of the semiconductor devices.

In another embodiment, the general structure of the semiconductor device is like the above-described planar semiconductor devices but is embodied as a trench semiconductor device. FIG. 2 shows a general structure of a semiconductor with a trench configuration (half-cell). Generally, any examples described regarding the planar semiconductor devices in this description may be implemented into the trench semiconductor devices even though these examples are not repeated herein again. In contrast to a planar semiconductor device, a trench semiconductor device may have a gate structure comprising a gate trench disposed in the SiC body 20 and adjacent to the source region 30. The gate trench may have a depth that is greater than a depth of the body region 20 and that is less than a depth of the drift region 10, wherein the gate dielectric 40 is disposed in the gate trench on a sidewall of the gate trench and a bottom surface of the gate trench. On a sidewall of the gate trench encompasses not only one side wall, for example the sidewall in the first half cell as shown in FIG. 2, but also any other sidewall, for example the side wall of the second half cell. The gate electrode 50 may be disposed on the gate dielectric 40. The gate dielectric is prepared and structured likewise as in the planar semiconductor devices described herein in the form of a multilayer laminate structure including alternating layers of the first dielectric material 41 and the second dielectric material 42 as shown in FIG. 2. Like the above-described planar systems, the gate dielectric may comprise more than the herein shown two layers 41,42, for example, two or more layers of the first dielectric material in combination with two or more layers of the second dielectric material alternatingly configured in the multilayer laminate structure. Further examples may include layers of a third or further dielectric material which may include Si-based, Al-based, or other high-k dielectric materials than the first and second dielectric materials.

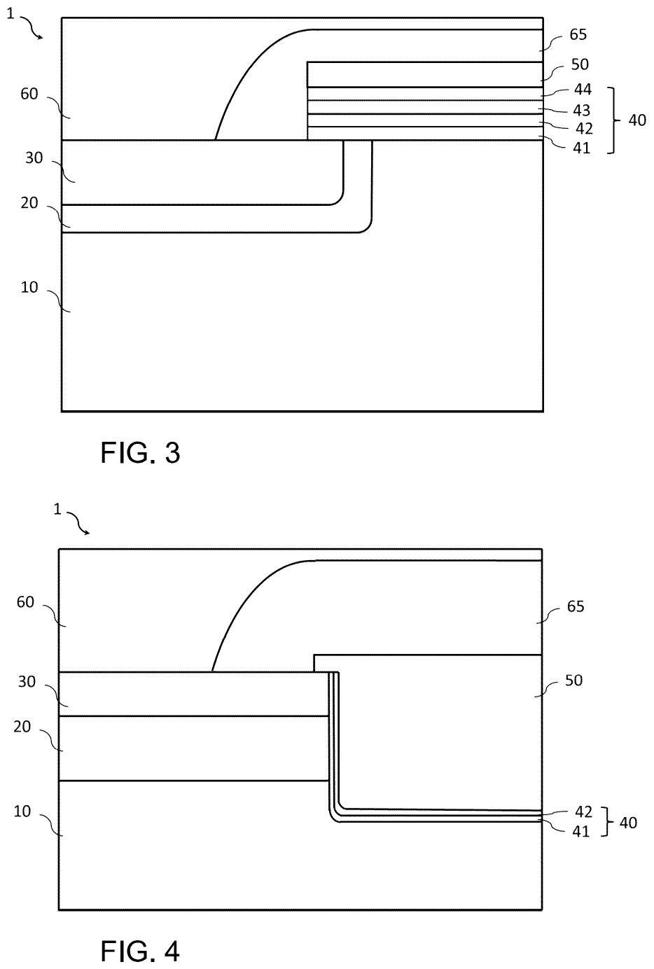

Further examples of semiconductor devices having the above described general planar and trench structures are shown in FIGS. 3 and 4. A half-cell of a planar MOSFET is shown in FIG. 3.

The cell structure of the MOSFET as semiconductor device 1 comprises a drift region 10 of a first conductivity type (e.g., n-doped SiC), a body region 20 of a second conductivity type (e.g., p-doped SiC), a source region 30 of the first conductivity type (e.g., n-doped SiC), and a gate structure with a gate dielectric 40 and a gate electrode 50. The gate dielectric 40 isolates the gate electrode 50 from the SiC body 20. The gate structure is deposited on a portion of the source region 30 and on a portion of the drift region 10, thereby providing a conductivity channel within the SiC body near the interface to the gate structure on which the gate structure is deposited. In some examples described herein, the gate dielectric 40 comprises a multilayer laminate structure including alternating layers of a first dielectric material 41,43 and of a second dielectric material 42,44, wherein the first and the second dielectric materials have a dielectric constant (also called k value or permittivity) of 4 or higher (cf. FIG. 3). Materials with a dielectric constant of more than 4 usually are known as high-k dielectrics, wherein particularly selected high-k dielectrics may have a k value of 9 or more, in particular, 20 or more. Such high-k dielectrics may be used instead of SiO₂ in the gate dielectric or in addition to SiO₂ dielectric layers to reduce the electric field in the gate dielectric of such semiconductor devices and are suitable to achieve improvements in the breakdown performance and RDSON performance. At the same time, the gate structure may be manufactured in a smaller size while enabling similar or even better insulating properties compared to SiO₂ gate structures in the semiconductor devices with a dielectric multilayer structure as described herein.

FIG. 4 shows a general structure of a semiconductor device 1 with a trench configuration (half-cell). Generally, any examples described regarding the planar semiconductor devices in this description may be implemented into the trench semiconductor devices even though these examples are not repeated herein again. In contrast to a planar semiconductor device, a trench semiconductor device 1 may have a gate structure comprising a gate trench disposed in the SiC body 20 and adjacent to the source region 30. The gate trench may have a depth that is greater than a depth of the body region 20 and that is less than a depth of the drift region 10, wherein the gate dielectric 40 is disposed in the gate trench on a sidewall of the gate trench and a bottom surface of the gate trench. The gate electrode 50 may be disposed on the gate dielectric 40. The gate dielectric is prepared and structured likewise as in the planar semiconductor devices described herein in the form of a multilayer laminate structure including alternating layers of a first dielectric material 41 and a second dielectric material 42 as shown in FIG. 4.

In the two alternative embodiments of the semiconductor device 1 shown in FIGS. 3 and 4, respectively, a source metal 60 may electrically contact the source region, wherein an interlayer dielectric 65 isolates the gate electrode 50 from the source metal 60. The gate electrode 50 may in some examples be made of or may comprise polycrystalline silicon (poly-Si). In this case, the interlayer dielectric 65 comprises a multilayer laminate structure (not shown in FIGS. 3 and 4) including alternating layers of a first dielectric material and of a second dielectric material, wherein the first and the second dielectric materials have a dielectric constant (k value) of 4 or higher. The first dielectric material may have an at least 0.3 eV higher conduction band offset and an at least 0.3 eV lower valence band offset than the second dielectric material. Separately or in combination, the first dielectric material may have a high conduction band offset but low valence band offset and the second dielectric material may have a low conduction band offset but high valence band offset. The offset (e.g., the valence band offset and the conduction band offset) of the first dielectric material and the second dielectric material is calculated to the SiC valence band and conduction band (e.g., the conduction band minimum) on the one side and the Fermi level of the poly-Si on the other side, respectively. The same high-k dielectric materials as used in the gate dielectric structure described before may be implemented in the interlayer dielectric. That is to say, the first dielectric material may have the same properties as the first dielectric material (or the second dielectric material) and the second dielectric material may have the same properties as the second dielectric material (or the first dielectric material, respectively).

In another example, the semiconductor device 1 with an interlayer dielectric 65 comprises a metal gate electrode 50 and the interlayer dielectric 65 comprises a multilayer laminate structure including alternating layers of a first dielectric material and of a second dielectric material, wherein the first and the second dielectric materials have a dielectric constant (k value) of 4 or higher. The first dielectric material may have an at least 0.3 eV higher conduction band offset and an at least 0.3 eV lower valence band offset than the second dielectric material. Separately or in combination, the first dielectric material may have a high conduction band offset but low valence band offset and the second dielectric material may have a low conduction band offset but high valence band offset, wherein the offset is calculated to the SiC valence and conduction bands (e.g., the conduction band minimum) on the one side and the Fermi level of the gate metal, respectively. The high-k dielectric materials may be selected from the same materials as in the gate dielectric structure described before.

The present disclosure also encompasses planar or trench semiconductor devices comprising a common gate structure, for example, based on SiO₂ as gate dielectric, and a source metal that electrically contacts the source region, wherein an interlayer dielectric isolates the gate electrode from the source metal. The gate electrode may in some examples be made of or comprise polycrystalline silicon (poly-Si). In this case, the interlayer dielectric may comprise a multilayer laminate structure including alternating layers of a first dielectric material and of a second dielectric material, wherein the first and the second dielectric materials have a dielectric constant (k value) of 4 or higher. The first dielectric material may have an at least 0.3 eV higher conduction band offset and an at least 0.3 eV lower valence band offset than the second dielectric material. Separately or in combination, the first dielectric material may have a high conduction band offset but low valence band offset and the second dielectric material may have a low conduction band offset but high valence band offset, wherein the offset is calculated to the poly-Si valence and conduction bands, respectively. The same high-k dielectric materials as used in the gate dielectric structure described before may be implemented in the interlayer dielectric. In case the gate electrode is made of or comprises a metal gate, which has a conduction band minimum, the offset may be calculated to the conduction band minimum of either the metal gate or the source metal.

In a further embodiment, the semiconductor device may further comprise a source metal that electrically contacts the source region, wherein an interlayer dielectric isolates the gate electrode from the source metal, and wherein the interlayer dielectric comprises alternating layers of a first dielectric material comprising or being silicon oxide and of a second dielectric material having a dielectric constant (k value) of 4 or higher. In this embodiment, the thickness of the layers of the first dielectric material is at most 5 nm. Furthermore, the interlayer dielectric may include layers of the first dielectric material as the first and the last layers of the multilayer laminate structure, respectively. In this embodiment, the layer thickness of the interlayer dielectric stack (e.g., the interlayer multilayer laminate structure) can be reduced because of the high-k second dielectric material without excessive tunneling currents across the interlayer dielectric layer stack (e.g., the interlayer multilayer laminate structure). Even if a high-k dielectric may enhance the capacitance between the source and the gate and may slow down switching, such an interlayer dielectric laminate structure of high-k dielectric materials may improve the overall performance of a semiconductor device. This indeed may be desired for power MOSFETs, for example.

In a further example of the semiconductor device as describe in one of the above embodiments at least one of the interlayer dielectric and the gate dielectric comprises at least two of the layers having a first dielectric material and at least two of the layers having a second dielectric material. At least two means that two, three, or more layers of the first dielectric material are arranged with two, three, or even more layers of a second dielectric material in an alternating manner. Alternating means that a dielectric layer stack may comprise a layer of a first dielectric material, a layer of a second dielectric material, a layer of a first dielectric material, and a layer of a second dielectric material in this order. Optionally, further first and second dielectric layers may follow this order of layers, wherein the last layer may be from a first or a second dielectric layer type. Alternatively, the alternating layer stack may start with a second dielectric layer, followed by a first dielectric layer, a second dielectric layer, and a further first dielectric layer, for example. Hence, the terms “first” and “second” do not identify which of these layers is the layer neighboring the gate or source electrode or the SiC substrate, respectively.

A semiconductor device according to a further example may comprise an interlayer dielectric which further includes an interface dielectric layer disposed between at least a portion of the source metal and the first layer of the multilayer laminate structure. Exemplified interface dielectric layers may be based on silicon oxides and/or nitrides such as silicon oxide (SiO₂) or mixed nitrides and oxides of Si. In this case, the Si based interface dielectric layer may be provided as thin as possible, for example 5 nm or less. In some examples described herein Al based oxides are excluded by definition for being suitably used as the first and second high-k dielectric materials. However, in these examples the Al based oxides, nitrides, or mixed oxides and nitrides may be arranged as the interface dielectric layer.

The gate dielectric of a further example of the semiconductor device may further include an interface dielectric layer disposed between at least a portion of the SiC body and the first layer of the multilayer laminate structure. Exemplified interface dielectric layers may be based on Si oxides and/or nitrides such as SiO₂ or mixed nitrides and oxides of Si. In this case, the Si based interface dielectric layer may be provided as thin as possible, for example 5 nm or less. In some examples described herein Al based oxides are excluded by definition for being suitably used as the first and second high-k dielectric materials. However, in these examples the Al based oxides, nitrides, or mixed oxides and nitrides may be arranged as the interface dielectric layer.

In some examples of the semiconductor devices described herein, the first and the second dielectric materials may have a band gap lower than 7.0 eV. Exemplified high-k dielectric materials are AlN (about 6.2 eV), HfO₂ (5.7 eV), ZrO₂ (5.6 eV), Ta₂O₅ (4.4 eV), and La₂O₅ (5.45 eV). Those small bandgap materials allegedly are not considered to sufficiently block holes and electron carriers in Si or SiC based semiconductor gate dielectric systems. When being used in the multilayer laminate structure as defined herein, however, these high-k dielectric materials are found to be sufficient to fulfill all requirements of the gate dielectric material, if they are arranged in a stack of alternating layers such that the first dielectric material has a high conduction band offset but low valence band offset, and the second dielectric material has a low conduction band offset but high valence band offset. Hence, the former meaning has been overcome by this special arrangement of at last two of these materials in the multilayer laminate structure. The specific selection of the first and second dielectric materials in line with the above general concept of the present disclosure enables to suppress or block the current tunneling of the holes and the electron carries from the substrate (e.g., SiC) side and/or from the gate electrode side in the same level. In this regard, it is important that either the first or the second dielectric material has a high band offset to the conduction band of the SiC and that the other dielectric material which has not a high band offset to the conduction band has at least a high band offset to the valance band. If this is realized in the multilayer laminate of alternating dielectric material layers, it is possible to reduce the bandgap of each of the high-k dielectric materials. Thus, materials with higher permittivity (higher k values) can suitably be implemented in the gate structure. The same general concept can be similarly applied with respect to the interlayer dielectric described herein for being disposed between at least a portion of the source material and the first layer of the multilayer laminate structure, for example.

In some examples, the first and/or second dielectric material in at least some of the layers of the multilayer laminate structure may comprise composite materials including two or more different high-k materials. Thus, the permittivity and the band offset of each of the layers of the layer stack in the multilayer laminate structure may be specifically varied according to their needs. The composite materials may include mixtures of two oxides with different cations or mixtures of oxides and nitrides of one cation, for example, while mixtures of other combinations of two or more high-k materials may be applied as well.

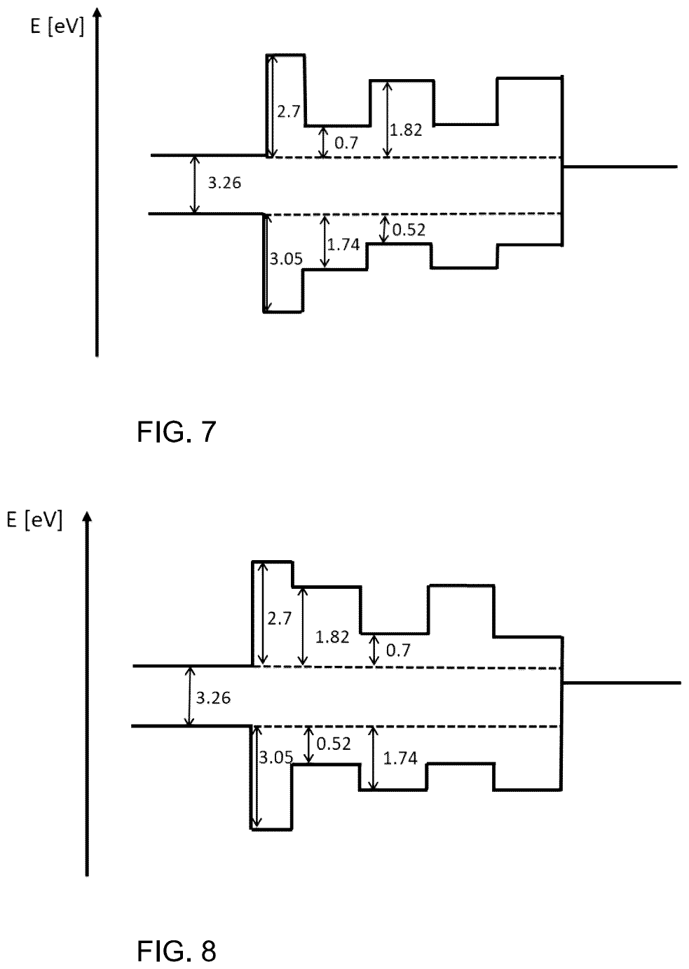

In FIGS. 7 and 8, semiconductor devices with similar dielectric multilayer laminate structures as described with regard to the band diagrams shown in FIGS. 5 and 6 are shown, except that an additional interface dielectric layer, here a thin SiO₂ layer (thickness about 5 nm) is provided as interface layer between the SiC substrate and the first layer of the multilayer laminate stack. In FIG. 7, the first layer of the multilayer stack is HfO₂ and the second layer is ZrO₂, while the order of the high-k layers is ZrO₂ and HfO₂ in the multilayer laminate stack shown in FIG. 8.

The multilayer laminate structure may, according to further examples, include further layers within the alternating layers of the first and second dielectric materials, wherein the further layers comprise a third or further dielectric material having a high-k value being different from the first and second dielectric materials. In this respect any of the herein identified high-k materials may be used regardless of their band offsets in case the stack includes layers of first and second dielectric materials with a sufficient thickness and band offset characteristic to suppress or block current tunneling as good as possible. Exemplified high-k materials may be those which have higher band offsets than described above, for example, Si or Al oxides or mixed oxides and nitrides.

Exemplified high-k materials with a high conduction band offset compared to the SiC conduction band are those having a band offset of 1.0 eV or higher, for example, between about 1.0-1.5 eV and 2.7 eV. Examples of high conduction band offset materials are, among others, Al₂O₃ (1.9 eV), AlN (1.3 eV), ZrO₂ (1.82 eV). High-k materials with a high valence band offset compared to the SiC valence band are those having a band offset of 1.0 eV or higher, for example between about 1.0-1.5 eV and 2.9 eV. Examples of high valence band offset materials are, among others, Al₂O₃ (1.84 eV), AlN (1.7 eV), HfO₂ (1.74 eV), Ta₂O₅ (1.54 eV), La₂O₃ (1.2 eV). Therefore, taking these band offset values in account, exemplified alternating layer stacks may be based on combinations of ZrO₂/AlN or ZrO₂/HfO₂ or ZrO₂/La₂O₃ or ZrO₂/Ta₂O₅ or AlN/Ta₂O₅.

In some examples, the first dielectric material has an offset to the conduction band of the SiC body material of at least 1.0 eV and the second dielectric material has an offset to the valence band of the SiC body material of at least 1.0 eV. In other examples, the first dielectric material has an offset to the valence band of the SiC body material of at least 1.0 eV and the second dielectric material has an offset to the conduction band of the SiC body material of at least 1.0 eV. At least 1.0 eV may include any value within the range between 1.0 eV and 2.5 or 2.7 eV, respectively, as described before.

According to some embodiments, it may be advantageous that the conduction band offsets and the valence band offsets of the first and second dielectric materials are not identical with or similar to each other but may have a distinctive difference. Therefore, the first dielectric material and the second dielectric material may have different conduction band values and valence band values, respectively. The difference is at least 0.3 eV at the side of the conduction band and the valence band, respectively. This difference in band values facilitates to improve blocking of hole or charge carrier tunneling phenomena in the semiconductor devices in which the gate dielectric and/or the interlayer dielectric are embodied accordingly.

The semiconductor device according to an alternative or the above-identified embodiments may further comprise a gate dielectric which has an overall k value higher than silicon oxide (SiO₂) and comprising a multilayer laminate structure including alternating layers of a first dielectric material having a band gap lower than 7.0 eV and of a second dielectric material having a band gap lower than 7.0 eV. In this embodiment, the first dielectric material may have an offset to the conduction band of the SiC body of at least 1.0 eV, and the second dielectric material may have an offset to the valence band of the SiC body material of at least 1.0 eV. In case the dielectric material is adjoined to the gate material (e.g., poly-Si or metal), the offset is calculated to the Fermi level of the gate material. Suitable high-k dielectric materials can be selected from the above-identified high-k materials. In this embodiment, Al₂O₃ having a band gap of about 7.0 eV may not fall within the definition of the first and second embodiments. However, among others, AlN, HfO₂, ZrO₂, Ta₂O₅, La₂O₃ would fall within the specifically selected high-k materials which would fall within the definition used for this embodiment. As it is known to the skilled person, these examples have a higher k value than Al₂O₃ and allow to further reduce the size of the semiconductor devices at all. Especially, the thickness of the gate dielectric may be further reduced when using selected nitrides or oxides from this list. As mentioned in the embodiments described herein before, the selected first dielectric material may have a high conduction band offset but low valence band offset, and the selected second dielectric material may have a high valence band offset and a low conduction band offset, wherein the offset is calculated to the silicon carbide valence and conduction bands, respectively.

If the semiconductor device is embodied with an interlayer dielectric in addition to the afore-mentioned gate dielectric or with a conventional gate dielectric, the interlayer dielectric may have an overall k value higher than silicon oxide (SiO₂) and may comprise a multilayer laminate structure including alternating layers of a first dielectric material having a band gap lower than 7.0 eV and of a second dielectric material having a band gap lower than 7.0 eV. In these embodiments, the first dielectric material may have an offset to the conduction band of the SiC body material or to the Fermi level of the source metal of at least 1.0 eV, and the second dielectric material may have an offset to the valence band of the SiC body material or to the Fermi level of the source metal of at least 1.0 eV. The same first and second dielectric materials as described in the former embodiment may be implemented. More particularly, among others, AlN, HfO₂, ZrO₂, Ta₂O₅, La₂O₃ would fall within the specifically selected high-k materials which would fall within the definition used for this embodiment. As it is known to the skilled person, these examples have a higher k value than Al₂O₃ and allow to further reduce the size of the semiconductor devices at all. Especially, the thickness of the interlayer dielectric may be further reduced when using selected nitrides or oxides from this list. In particular, the selected first dielectric material may have a high conduction band offset but low valence band offset, and selected the second dielectric material may have a high valence band offset and a low conduction band offset, wherein the offset is calculated to the silicon carbide valence and conduction bands, respectively.

In some examples of the semiconductor devices according to any one of the above described embodiments, the thickness of the layers in the multilayer laminate structure may vary across the thickness of at least one of the gate dielectric or interlayer dielectric, if present in the device structure. For example, a thick layer of a first dielectric may be combined with a thick layer of a second dielectric. The thickness may be selected such that the tunneling of holes or charge carries through the gate dielectric or the interlayer dielectric may be reduced to a low value or blocked at all. Of course, depending on the permittivity of the first and second dielectric materials used in this laminate structure, two or more alternating layers may be arranged in the dielectric structure. In some examples the use of two layers is enough. However, as the dielectric material may have either a low conduction band offset or low valence band offset to the neighboring SiC or material of the gate electrode (e.g., poly-Si or a metal gate), it is possible to suppress either electron injection from the gate electrode (high valence band offset) or electron injection from SiC (high conduction band offset) during the application of a positive gate voltage. In addition, the arrangement having a first dielectric with a high valence band offset may suppress electron injection form SiC during the application of a negative potential at the gate. In case a material having a high conduction band offset is neighboring to the SiC substrate, suppressing hole injection from the gate during the application of a negative gate voltage may be observed or guaranteed in later applications of the semiconductor devices.

According to further embodiments, the semiconductor device may have a gate electrode comprising a metal gate or doped metal gate. Using a metal gate instead of polycrystalline Si allows a band engineering at the gate electrode. Thus, the Fermi level of the metal gate may be adjusted such that it is nearly at the middle of the height of the bandgap of the neighboring dielectric material. Exemplified metal gate materials are TiN or metal gates with La or Al doping. TiN has a lower Fermi level than for high n-doped poly-Si, for example. If the TIN is doped with La, for example, the Fermi level may be increased to higher energies. In contrast thereto, Al doping reduces the Fermi level compared to the undoped status. Therefore, it is possible to tune the work function of the interface by La- and/or Al-based intermediate layers. Thus, the band offset between the gate and the high-k dielectric may be increased (higher or lower energy value adjustment depending on the high-k conduction and valence band energies). Because of this gate workfunction tuning at the gate electrode, the electron tunneling into the gate dielectric can be suppressed.

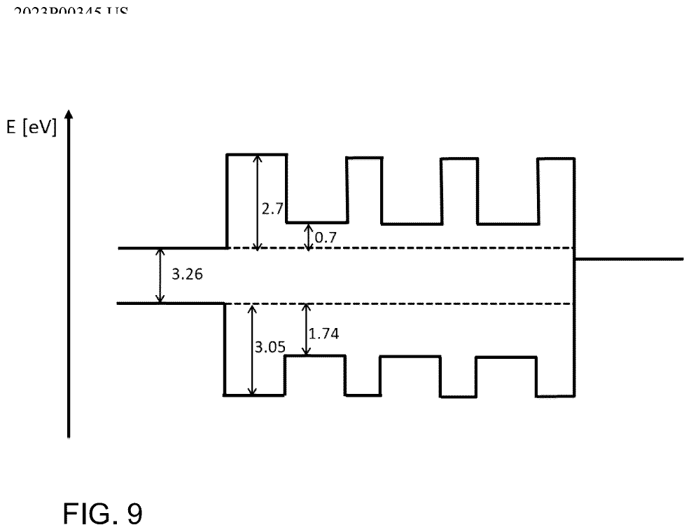

In another embodiment described herein, a semiconductor device comprising a silicon carbide (SiC) body is embodied with a drift region of a first conductivity type, a body region of a second conductivity type, and a source region of the first conductivity type. The semiconductor device may include a gate structure comprising a gate electrode and a gate dielectric that isolates the gate electrode from the SiC body, wherein the gate structure is disposed adjacent to the source region, the body region and the drift region. The general constitution is as described with regard to the other embodiments. However, the gate dielectric according to this embodiment comprises a multilayer laminate structure including alternating layers of a first dielectric material comprising or being silicon oxide and of a second dielectric material having a dielectric constant (k value) of 4 or higher, wherein the thickness of the layers of the first dielectric material is at most 5 nm, and the gate dielectric includes layers of the first dielectric material as the first and the last layers of the multilayer laminate structure. An exemplary band diagram of a gate dielectric according to this embodiment is shown in FIG. 9. A first thick layer of SiO₂ having an overall band gap of 9.0 eV is shown in FIG. 9 adjoining the SiC body with a band gap of 3.26 eV. Alternating layers of HfO₂ (band gap of 5.7 eV) and thinner SiO₂ layers are provided in this dielectric structure. The respective offsets to the SiC valence and conduction bands are given in FIG. 9. Generally, the first dielectric may be silicon dioxide if the superlattice of alternating layers of at least first and second dielectric materials comprises a high-k dielectric material with sufficient thickness and permittivity. Even though current tunneling has been observed if the layer thickness of silicon oxide layers is too small in conventional semiconductor devices, the arrangement with one or more alternating layers of a second dielectric material suppresses the tunneling phenomena. Thus, the layers of a second dielectric material may be arranged in an alternating manner with a first dielectric material comprising or being SiO₂. The layer thickness of the first dielectric material may be at most 5 nm which is rather low compared to conventional semiconductor devices based in silicon oxide dielectric structures. The high band offsets of SiO₂ allow to suppress current tunneling together with the high-k dielectric material layers provided in an alternating multilayer structure. Of course, the second dielectric material layers may comprise the same high-k material or may be constituted of different high-k materials, that means at least one second high-k dielectric material and a third or fourth high-k dielectric material arranged in combination with each other in this multilayer laminate structure, also called superlattice structure. Similar effects as in the other embodiments described herein have been observed.

In an example of the above embodiment, the multilayer laminate structure may comprise a third or further dielectric material layer comprising a material selected from a Si-based, Al-based, or high-k dielectric material other than the first and second dielectric materials. Thus, a dielectric laminate structure with a thin SiO₂ layer, a layer of a first high-k dielectric material, and a one or more layers of a second and further high-k material may be combined and stacked repeatedly in this or any other order in the dielectric laminate structure. In order to achieve the above described effects, the first, second, third, and further dielectric materials may be selected such that they have the respective band offsets to the valence and conduction bands of the SiC.

In some examples, the semiconductor device of the aforementioned embodiment may provide a gate structure comprising a gate trench disposed in the SiC body and adjacent to the source region, the gate trench having a depth that is greater than a depth of the body region and that is less than a depth of the drift region. The gate dielectric may be disposed in the gate trench on a sidewall of the gate trench and a bottom surface of the gate trench, wherein the gate electrode may be disposed on the gate dielectric. Therefore, all features described with regard to planar embodiments of the semiconductor devices described herein may be implemented into a so-called trench semiconductor device, for example a trench MOSFET or IGBT with a trench gate structure.

According to other examples, the afore-mentioned semiconductor devices may further comprise a source metal that electrically contacts the source region, wherein an interlayer dielectric isolates the gate electrode from the source metal. In some examples, the interlayer dielectric may comprise a multilayer laminate structure including alternating layers of a first dielectric material and of a second dielectric material, wherein the first and the second dielectric materials have a dielectric constant (k value) of 4 or higher, the first dielectric material has a high conduction band offset but low valence band offset and the second dielectric material has a low conduction band offset but high valence band offset, wherein the offset is calculated to the conduction band minimum of the source metal. Even though this interlayer dielectric structure is described herein with regard to the embodiments including a similarly composed gate dielectric structure, these interlayer dielectrics may be suitably used in conventional semiconductor devices with, for example, silicon oxide dielectric gate structures in the same manner.

According to alternative examples of semiconductor devices having an interlayer dielectric isolating the gate electrode from the source metal as described above, the interlayer dielectric may comprise alternating layers of a first dielectric material being or comprising silicon oxide and of a second dielectric material having a dielectric constant (k value) of 4 or higher, wherein the thickness of the layers of the first dielectric material is at most 5 nm, and the interlayer dielectric includes layers of the first dielectric material as the first and the last layers of the multilayer laminate structure. Such alternative dielectric layer structures comprising thin silicon oxide (SiO₂) layers may also be suitably used in conventional semiconductor devices with, for example, silicon oxide dielectric gate structures.

Moreover, the disclosure provides a method for manufacturing a semiconductor device, especially, a semiconductor device including a silicon carbide (SiC) body, wherein the SiC body comprises a drift region of a first conductivity type, a body region of a second conductivity type, and a source region of the first conductivity type, and wherein the SiC body is provided with a gate structure comprising a gate electrode and a gate dielectric that isolates the gate electrode from the SiC body, wherein the gate structure is disposed adjacent to the source region, the body region and the drift region. In this regard, planar or trench structures may be provided in the semiconductor device in the usual manner known to the person skilled in this technical field. In those semiconductor devices, the gate dielectric is deposited on parts of the SiC body in a multilayer laminate structure including alternating layers of a first dielectric material and of a second dielectric material. In some examples, the method comprises the action to provide the multilayer structure such that the first and the second dielectric materials have a dielectric constant (k value) of 4 or higher, the first dielectric material has a high conduction band offset but low valence band offset and the second dielectric material has a low conduction band offset but high valence band offset, wherein the offset is calculated to the silicon carbide valence and conduction bands, respectively. In an alternative example of the method, the method comprises the action of providing the multilayer structure such that the first dielectric material comprises or is silicon oxide and the second dielectric material has a dielectric constant (k value) of 4 or higher, wherein the thickness of the layers of the first dielectric material is at most 5 nm, and the interlayer dielectric includes layers of the first dielectric material as the first and the last layers of the multilayer laminate structure.

The generation of the multilayer structure is conducted by standard procedures known in the art. The use or selection of the specific dielectric materials is carried out as described in the embodiments regarding the alternative semiconductor devices based on the characteristics and parameters of the dielectric materials, such as the k-value, the band gap, the conduction or valence band offsets to SiC or the conduction band minimum or Fermi levels of the metals used in the substrate, the source or the gate structures. In this regard, the method encompasses actions as to specifically select the material combinations such that the respective band offsets or band gap values are adjusted or varied as described before. In some examples, the Fermi level of the gate electrode may be adjusted based on the valence and conduction band offsets of the dielectric material layer adjoined to the gate electrode. Thus, this allows a Fermi level engineering in the metal gate depending on the combination of the high-k materials and the respective band offsets in the dielectric multilayer laminate structures used in the respective embodiment described herein. This Fermi level engineering can be used for tuning the band gap offsets and to improve or optimize the conduction and/or valence band offset levels to the Fermi level of the gate electrode for example.

Although specific examples have been illustrated and described herein, it will be appreciated by those of ordinary skill in the art that a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the disclosure and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the disclosure, as well as specific examples thereof, are intended to encompass equivalents thereof.

1. A semiconductor device comprising a silicon carbide (SiC) body, comprising:
a drift region of a first conductivity type;
a body region of a second conductivity type;
a source region of the first conductivity type; and
a gate structure comprising a gate electrode and a gate dielectric that isolates the gate electrode from the SiC body,
wherein:
the gate structure is disposed adjacent to at least one of the source region, the body region or the drift region,
the gate dielectric comprises a multilayer laminate structure comprising a first layer of a first dielectric material and a second layer of a second dielectric material.

2. The semiconductor device according to claim 1, wherein:
the first dielectric material and the second dielectric material have a dielectric constant (k value) of 4 or higher; and
at least one of the first dielectric material has an at least 0.3 eV higher conduction band offset and an at least 0.3 eV lower valence band offset than the second dielectric material or the second dielectric material has an at least 0.3 eV higher conduction band offset and an at least 0.3 eV lower valence band offset than the first dielectric material.

3. The semiconductor device according to claim 1, wherein at least one of:
the first dielectric material has a high conduction band offset but low valence band offset and the second dielectric material has a low conduction band offset but high valence band offset; or
the second dielectric material has a high conduction band offset but low valence band offset and the first dielectric material has a low conduction band offset but high valence band offset.

4. The semiconductor device according to claim 1, wherein:
the gate structure comprises a gate trench disposed in the SiC body and adjacent to the source region, the gate trench having a depth that is greater than a depth of the body region and that is less than a depth of the drift region,
the gate dielectric is disposed in the gate trench on a sidewall of the gate trench and a bottom surface of the gate trench; and
the gate electrode is disposed on the gate dielectric.

5. The semiconductor device according to claim 1, further comprising a source metal that electrically contacts the source region,
wherein:
an interlayer dielectric isolates the gate electrode from the source metal;
the gate electrode comprises polycrystalline silicon (poly-Si); and
the interlayer dielectric comprises an interlayer multilayer laminate structure comprising a first layer of a first dielectric material and a second layer of a second dielectric material; and
the first dielectric material and the second dielectric material of the interlayer dielectric have a dielectric constant (k value) of 4 or higher, wherein at least one of:
the first dielectric material has an at least 0.3 eV higher conduction band offset and an at least 0.3 eV lower valence band offset than the second dielectric material; or
the first dielectric material has a high conduction band offset but low valence band offset and the second dielectric material has a low conduction band offset but high valence band offset.

6. The semiconductor device according to claim 1, further comprising a source metal that electrically contacts the source region,
wherein:
an interlayer dielectric isolates the gate electrode from the source metal;
the gate electrode comprises a metal gate electrode;
the interlayer dielectric comprises an interlayer multilayer laminate structure comprising a first layer of a first dielectric material and a second layer of a second dielectric material; and
the first dielectric material and the second dielectric material of the interlayer dielectric have a dielectric constant (k value) of 4 or higher, wherein at least one of:
the first dielectric material has an at least 0.3 eV higher conduction band offset and an at least 0.3 eV lower valence band offset than the second dielectric material; or
the first dielectric material has a high conduction band offset but low valence band offset and the second dielectric material has a low conduction band offset but high valence band offset.

7. The semiconductor device according to claim 1, further comprising a source metal that electrically contacts the source region,
wherein:
an interlayer dielectric isolates the gate electrode from the source metal;
the interlayer dielectric comprises a first layer of a first dielectric material comprising silicon oxide and a second layer of a second dielectric material;
at least one of the first dielectric material or the second dielectric material of the interlayer dielectric having a dielectric constant (k value) of 4 or higher;
the thickness of the first layer of the first dielectric material is at most 5 nm; and
the interlayer dielectric comprises layers of the first dielectric material as the first and the last layers of the multilayer laminate structure.

8. The semiconductor device according to claim 1, wherein the gate dielectric comprises at least two layers having the first dielectric material and at least two layers having a second dielectric material.

9. The semiconductor device according to claim 1, wherein at least one of the gate dielectric or an interlayer dielectric comprises a third dielectric material layer comprising at least one of a Si-based material, an Al-based material, or a high-k dielectric material.

10. The semiconductor device according to claim 1, wherein the gate dielectric further comprises an interface dielectric layer disposed between at least a portion of the SiC body and the first layer of the multilayer laminate structure.

11. The semiconductor device according to claim 10, wherein the interface dielectric layer comprises silicon oxide.

12. The semiconductor device according to claim 1, wherein the first dielectric material and the second dielectric material have a band gap lower than 7.0 eV.

13. The semiconductor device according to claim 1, wherein:
the first dielectric material has an offset to the conduction band of the SiC body material of at least 1.0 eV; and
at least one of:
the second dielectric material has an offset to the valence band of the SiC body material of at least 1.0 eV; or
the first dielectric material has an offset to the valence band of the SiC body material of at least 1.0 eV and the second dielectric material has an offset to the conduction band of the SiC body material of at least 1.0 eV.

14. The semiconductor device according to claim 1, wherein at least one of an interlayer dielectric or the gate dielectric has an overall k value higher than silicon oxide (SiO₂), the semiconductor device further comprising:
a multilayer laminate structure comprising a first layer of a first dielectric material having a band gap lower than 7.0 eV and a second layer of a second dielectric material having a band gap lower than 7.0 eV, wherein the first dielectric material has an offset to the conduction band of the SiC body material or source metal of at least 0.8 eV and the second dielectric material has an offset to the valence band of the SiC body material or source metal of at least 0.8 eV.

15. The semiconductor device according to claim 1, wherein the thickness of layers in the multilayer laminate structure varies across the thickness of at least one of the gate dielectric or an interlayer dielectric.

16. A semiconductor device comprising a silicon carbide (SiC) body, comprising:
a drift region of a first conductivity type;
a body region of a second conductivity type;
a source region of the first conductivity type; and
a gate structure comprising a gate electrode and a gate dielectric that isolates the gate electrode from the SiC body,
wherein:
the gate structure is disposed adjacent to at least one of the source region, the body region or the drift region;
the gate dielectric comprises a multilayer laminate structure comprising a first layer of a first dielectric material comprising silicon oxide and a second layer of a second dielectric material; and
the gate dielectric comprises layers of the first dielectric material as the first and the last layers of the multilayer laminate structure.

17. The semiconductor device according to claim 15, wherein the multilayer laminate structure comprises a third dielectric material layer comprising at least one of a Si-based material, an Al-based material, or a high-k dielectric material.

18. The semiconductor device according to claim 15, wherein:
the gate structure comprises a gate trench disposed in the SiC body and adjacent to the source region, the gate trench having a depth that is greater than a depth of the body region and that is less than a depth of the drift region;
the gate dielectric is disposed in the gate trench on a sidewall of the gate trench and a bottom surface of the gate trench; and
the gate electrode is disposed on the gate dielectric.

19. A method for manufacturing a semiconductor device including a silicon carbide (SIC) body, wherein the SiC body comprises a drift region of a first conductivity type, a body region of a second conductivity type, and a source region of the first conductivity type;
and wherein the SiC body is provided with a gate structure comprising a gate electrode and a gate dielectric that isolates the gate electrode from the SiC body, wherein the gate structure is disposed adjacent to the source region, the body region and the drift region;
wherein the gate dielectric is deposited on parts of the SiC body in a multilayer laminate structure comprising a first layer of a first dielectric material and a second layer of a second dielectric material.

20. The method for manufacturing a semiconductor device according to claim 19, wherein:
the first dielectric material and the second dielectric material have a dielectric constant (k value) of 4 or higher;
the first dielectric material has an at least 0.3 eV higher conduction band offset and an at least 0.3 eV lower valence band offset than the second dielectric material;
the second dielectric material has an at least 0.3 eV higher conduction band offset and an at least 0.3 eV lower valence band offset than the first dielectric material;
the first dielectric material comprises silicon oxide and the second dielectric material has a dielectric constant (k value) of 4 or higher;
the thickness of the layers of the first dielectric material is at most 5 nm; and
the interlayer dielectric comprises layers of the first dielectric material as the first and the last layers of the multilayer laminate structure.
